(19) United States
(12) Patent Application Publication
(10) Pub. No.: US 2026/0161101 A1
(43) Pub. Date: Jun. 11, 2026

(54) OPTICAL SYSTEM AND PROJECTION EXPOSURE SYSTEM

(71) Applicant: Carl Zeiss SMT GmbH, Oberkochen (DE)

(72) Inventors: Johannes KRUIS, Oberkochen (DE); Eugen DOETZEL, Ulm (DE)

(21) Appl. No.: 19/465,892

(22) Filed: Jan. 30, 2026

Related U.S. Application Data
(63) Continuation of application No. PCT/EP2024/069582, filed on Jul. 11, 2024.

(30) Foreign Application Priority Data
Aug. 9, 2023 (DE) 10 2023 207 632.2

(51) Int. Cl. G03F 7/00

(52) U.S. Cl. CPC G03F 7/70825

(57) ABSTRACT

An optical system for projection exposure apparatus comprises: an optical assembly having an optical element; a manipulator frame bearing the optical assembly; and a clamping assembly attached to the manipulator frame switchable from a closed state, in which the clamping assembly establishes a mechanical connection between the optical assembly and the manipulator frame, to an open state, in which the mechanical connection between the optical assembly and the manipulator frame is released, and vice versa.

### CROSS-REFERENCE TO RELATED APPLICATIONS

The present application is a continuation of, and claims benefit under 35 USC 120 to, international application No. PCT/EP2024/069582, filed Jul. 11, 2024, which claims benefit under 35 USC 119 of German Application No. 10 2023 207 632.2, filed Aug. 9, 2023. The entire disclosure of each of these applications is incorporated by reference herein.

### FIELD

The present disclosure relates to an optical system for a projection exposure apparatus and to a projection exposure apparatus having such an optical system.

### BACKGROUND

Microlithography is used to produce microstructured components, such as for example integrated circuits. The microlithography process is carried out using a lithography apparatus having an illumination system and a projection system. The image of a mask (reticle) illuminated via the illumination system is projected here via the projection system onto a substrate, for example a silicon wafer, which is coated with a light-sensitive layer (photoresist) and is arranged in the image plane of the projection system, in order to transfer the mask structure to the light-sensitive coating of the substrate.

Driven by the desire for ever smaller structures in the production of integrated circuits, EUV lithography apparatuses that use light with a wavelength in the range of 0.1 nm to 30 nm, such as 13.5 nm, and DUV lithography apparatuses that use light with a wavelength in the range of 30 nm to 250 nm are currently under development. For example in the case of such EUV lithography apparatuses, because of the high absorption of light at this wavelength by most materials, reflective optical units, i.e. mirrors, are typically used instead of—as previously—refractive optical units, i.e. lens elements.

It is generally desirable to be able to swap mirrors of this type at the use location of such a lithography apparatus. Due to the confined space conditions and the desired tolerances to be observed when swapping a mirror of this type, this can be associated with a large outlay in terms of time and labor and therefore is conventionally not possible at the use location of the lithography apparatus.

### SUMMARY

The present disclosure seeks to provide provide an improved optical system.

In an aspect, the disclosure provides an optical system for a projection exposure apparatus. The optical system comprises an optical assembly having an optical element, a manipulator frame, which bears the optical assembly, and a clamping assembly which is attached to the manipulator frame and which can be switched from a closed state, in which the clamping assembly establishes a mechanical connection between the optical assembly and the manipulator frame, to an open state, in which the mechanical connection between the optical assembly and the manipulator frame is released, and vice versa. In this case, the clamping assembly comprises a contact element which is connected to the optical element, a groove element which is connected to the manipulator frame and on which the contact element rests, and a locking unit for mechanically connecting the contact element to the groove element in the closed state of the clamping assembly, or wherein the contact element is connected to the manipulator frame, and the groove element is connected to the optical element, wherein the contact element comprises a spherical-cap-shaped contact portion, and the groove element comprises a V-shaped groove with two contact surfaces that are oriented obliquely with respect to each other, wherein the contact portion rests on the contact surfaces, or wherein the contact element and the groove element bear against each other on a surface contact or on a tetrahedron-shaped contact, wherein the locking unit comprises a locking element and a drive element for driving the locking element, and wherein the drive element is configured to switch the locking element from a locked state, in which the locking element engages behind the contact element in order to establish a form-fitting connection between the locking element and the contact element, to an unlocked state, in which the form-fitting connection between the locking element and the contact element is released, and vice versa.

The clamping assembly allows the optical assembly to be connected to the manipulator frame as often as desired and to be separated from the latter again. As a result, the optical assembly can be swapped in the field.

The optical system can be suitable both for EUV lithography and for DUV lithography. The optical system may be a projection optics unit or a part of a projection optics unit in the projection exposure apparatus. However, the optical system may also be an illumination optics unit or part of an illumination optics unit in the projection exposure apparatus. The optical system may comprise multiple optical assemblies. The optical assembly can be a mirror or a mirror module or may be referred to as such. The optical assembly may furthermore be a mirror assembly or be referred to as such.

The optical element may be a mirror such as, such as a DUV mirror or an EUV mirror. However, the optical element may also be a lens element. The optical element can comprise an optically effective surface, such as a mirror surface, which is configured to reflect illumination radiation, such as DUV radiation or EUV radiation. The optically effective surface may be realized with the aid of a coating.

In addition to the optical element, the optical assembly may have a mount which bears the optical element. For example, the optical element is adhesively bonded to the mount. However, the mount is optional. In the case that no frame is provided, the clamping assembly may directly connect the optical element to the manipulator frame. In the present case, the manipulator frame “bearing” the optical assembly means that, in particular, the manipulator frame is capable of absorbing a weight of the optical assembly or of the optical element.

The manipulator frame can be assigned multiple actuators, for example three actuators, with the aid of which it is possible to modify or adjust a pose of the manipulator frame together with the optical assembly. The manipulator frame thus can be actuatable. The optical assembly generally has six degrees of freedom, specifically three translational degrees of freedom in a first spatial direction or x-direction, a second spatial direction or y-direction and a third spatial direction or z-direction, and also three rotational degrees of freedom about the x-direction, the y-direction and the z-direction. This means that a position and an orientation of the optical assembly may be determined or described using the six degrees of freedom.

The “position” of the optical assembly should be understood to mean in particular its coordinates in relation to the x-direction, the y-direction and the z-direction. The “orientation” of the optical assembly should be understood to mean in particular its tilt with respect to the three directions. That is to say, the optical assembly can be tilted about the x-direction, the y-direction and/or the z-direction. This gives the six degrees of freedom for the position and orientation of the optical assembly. A “pose” of the optical assembly comprises both its position and its orientation. The term “pose” is accordingly replaceable by the wording “position and orientation”, and vice versa.

The manipulator frame together with the optical assembly can be adjusted or aligned with the aid of the actuators. Accordingly, the manipulator frame may be referred to as an adjustable or alignable manipulator frame. An “adjustment” or “alignment” should be understood to mean in particular a change in the pose of the optical assembly or of the manipulator frame together with the optical assembly. Alternatively, the manipulator frame together with the optical assembly may also be non-actuated.

Optionally, multiple clamping assemblies are provided. For example, exactly three clamping assemblies may be provided, with these being arranged distributed uniformly around an axis of symmetry or central axis of the optical assembly or of the optical element. For example, the clamping assemblies may be arranged offset from one another by 120°. The clamping assemblies may be, e.g., screwed to the manipulator frame. In this case it is possible that at least one of the clamping assemblies can be disassembled from the manipulator frame. This can help facilitate swapping of the optical assembly. The can apply to swaps in a plane spanned by the x-direction and the y-direction. Swapping in the z-direction is also possible without a clamping assembly that can be disassembled.

In the closed state, the clamping assembly can apply a clamping force to the optical assembly, for example to the mount of the optical assembly or to a mount strut assembled on the mount. Optionally, the mount strut correspondingly has two decoupling planes, which prevent parasitic forces from being applied to the optical element. Accordingly, it is desirable for the clamping assembly to be prevented from pressing directly onto the mount. Decoupling elements, for example in the form of flexures, may be provided for decoupling purposes.

The clamping force is not applied to the optical assembly in the open state. Accordingly, the optical assembly is without force or force-free in the open state. In the present case, “without force” or “force-free” means that the clamping force does not act. However, this does not rule out the weight of the optical assembly acting on the manipulator frame even in the open state.

A “mechanical connection” between the optical assembly and the manipulator frame should be understood to mean that in particular a releasable connection is established between the optical assembly and the manipulator frame, and it connects the optical assembly and the manipulator frame in such a way that the optical assembly is not separable from the manipulator frame in the closed state of the clamping assembly. Hence, the mechanical connection is implemented by the clamping assembly. The mechanical connection is releasable by virtue of switching the clamping assembly into the open state. As soon as the clamping assembly is in the open state, the optical assembly may be released from the manipulator frame again. For example, a line contact is established between the mount strut and the clamping assembly. A force transmission path extends into the manipulator frame via arm portions of the mount struts.

For example, the mechanical connection is a form-fitting connection. A form-fitting connection arises when two connecting partners, the clamping assembly and the optical assembly, such as the mount of the optical assembly, in the present case, engage into or behind one another. A form-fitting connection may be established and released again as often as desired. The form-fitting connection between the clamping assembly and the optical assembly is established by switching the clamping assembly from the open state into the closed state. The form-fitting connection is released by virtue of switching the clamping assembly into the open state from the closed state.

In the present case, a mechanical connection may be understood to mean in particular a releasable clamping connection that is established with the aid of the clamping assembly. For example, the mechanical connection between the optical assembly and the manipulator frame can be established by virtue of the clamping assembly engaging behind the optical assembly or engaging therein or applying the clamping force to the optical assembly.

The clamping assembly can comprise a contact element which is connected to the optical element, a groove element which is connected to the manipulator frame and on which the contact element rests, and a locking unit for mechanically connecting the contact element to the groove element in the closed state of the clamping assembly. Alternatively, the contact element is connected to the manipulator frame, and the groove element is connected to the optical element.

For example, the contact element is adhesively bonded to a rear side of the optical element. Alternatively, the contact element may also be arranged on the front side of the optical element, such as next to the optically effective surface. For example, the groove element is screwed to the manipulator frame. Optionally, multiple contact elements and multiple groove elements are provided. For example, exactly three contact elements and exactly three groove elements may be provided, with each contact element being assigned a groove element. For example, two of the aforementioned degrees of freedom may be assigned to each groove element. However, it is not necessary to provide exactly three contact elements and three groove elements. The clamping assembly may also be used to limit specific degrees of freedom. For example, a tetrahedron may be provided. Six degrees of freedom can be defined by way of six contact surfaces. However, internal degrees of freedom may also be defined. To this end, any desired number of clamping assemblies may be provided. With the aid of the locking unit, a form-fitting connection can be established between the contact element and the groove element.

The contact element can comprise a spherical-cap-shaped contact portion, and the groove element can comprise a V-shaped groove with two contact surfaces that are oriented obliquely with respect to each other, with the contact portion resting on the contact surfaces. Alternatively, the contact element and the groove element bear against each other on a surface contact or on a tetrahedron-shaped contact.

For example, the contact portion rests on the contact surfaces by way of two punctiform contacts. In the present case, a “spherical cap” is understood to mean a portion of a sphere. Alternatively, the contact portion may also be cylindrical. Optionally, a decoupling element is arranged between the optical element and the contact element. For example, a receiving portion of the contact element may also be provided between the decoupling element and the contact portion. That is to say, the contact portion is coupled to the decoupling element by way of the receiving portion. The decoupling element can serve for mechanically decoupling the contact portion from the optical element. For example, the decoupling element may comprise one or more cardan joints and/or leaf spring elements and/or flexures. In the present case, a “flexure” should be understood to mean a region of a component which, by bending and/or torsion, allows a relative movement between two rigid body regions. In the present case, e.g. the receiving portion and the optical element may function as rigid body regions, between which the decoupling element is provided as a flexure. For example, the two contact surfaces are inclined obliquely to each other at an angle of 90°.

The locking unit comprises a locking element and a drive element for driving the locking element, wherein the drive element is configured to switch the locking element from a locked state, in which the locking element engages behind the contact element in order to establish a form-fitting connection between the locking element and the contact element, to an unlocked state, in which the form-fitting connection between the locking element and the contact element is released, and vice versa.

In the form-fitting connection, parasitic effects can be prevented from being transmitted to the optical element by a force action. The aforementioned decoupling planes are provided for this reason. For example, the drive element is suitable for rotating the locking element about a central axis or axis of symmetry of the clamping assembly and for moving the locking element linearly along the axis of symmetry. For example, the drive element may comprise an electric, a hydraulic or a pneumatic drive or a piezo drive. Furthermore, the drive element may also comprise a gearing. In the locked state, the locking element engages around or engages behind the contact portion of the contact element for example. For example, at least portions of the locking element are received in the receiving portion of the contact element in the locked state. Appropriately controlling the drive element causes the contact element to be pressed against the groove element with the aforementioned clamping force. The clamping force is not introduced into the optical element by virtue of the contact element being directly connected to the optical element and mechanically decoupled from the latter with the aid of the decoupling element. The clamping force may optionally be measured with the aid of a sensor system. A feedback loop allowing control by way of the clamping force can be generated in that case. Moreover, anomalies could be detected.

According to an embodiment, the contact element has a perforation, wherein the locking element comprises a head portion, wherein the head portion engages behind the contact element in the locked state in order to establish the form-fitting connection between the locking element and the contact element, and wherein the head portion can only be guided through the perforation in the unlocked state.

For example, the contact element may be placed on the groove element in the unlocked state. In the process, the locking element is threaded through the perforation provided in the contact element. For example, the perforation is provided at or in the contact portion of the contact element. Optionally, the perforation in the contact portion is in the form of an elongate hole. In this context, the perforation may have an oval or a rectangular geometry. However, the geometry of the perforation may be chosen as desired for as long as the head portion of the locking element can engage behind the contact element. To this end, the perforation may have an axisymmetric or asymmetric embodiment to ensure the aforementioned functionality. The head portion can be cuboid. The head portion can be connected to the drive element with the aid of a cylindrical shaft portion. The locking element can be guided through a perforation provided centrally in the groove element. However, in so doing, it is desirable that only the shaft portion can be guided through this perforation. Optionally, the head portion cannot be guided through the perforation in the groove element. The perforation provided on the contact element can be rectangular and can have a geometry such that the head portion can be guided through the perforation of the contact element in the unlocked state. Rotating the head portion with respect to the perforation can cause the head portion to engage behind the contact portion of the contact element such that the contact element can no longer be lifted off the groove element.

According to an embodiment, the clamping assembly comprises a clamping element and a drive element for displacing the clamping element in order to switch the clamping assembly from the closed state to the open state and vice versa.

For example, the drive element is suitable for displacing the clamping element linearly. For example, the clamping element is configured to apply the clamping force to the respective mount strut of the optical assembly. The drive element may comprise an electric, a pneumatic or a hydraulic drive or a piezo drive. The clamping element can be lifted off the respective mount strut and lowered onto the latter again with the aid of the drive element, in order to apply the clamping force to the mount strut.

According to an embodiment, the clamping element is operatively connected to the drive element with the aid of a threaded spindle.

For example, the threaded spindle has a male thread. The clamping element has a female thread which corresponds to the male thread of the threaded spindle and which is provided in a threaded bore introduced into the clamping element. The clamping element can move up or down along the threaded spindle when the threaded spindle is rotated with the aid of the drive element. The threaded spindle is mounted on the manipulator frame. A planar base element on which the threaded spindle is mounted may be provided to this end. The base element may be screwed to the manipulator frame.

According to an embodiment, at least portions of the clamping element and/or the threaded spindle are arranged within a bellows.

For example, the bellows may be made of rubber. However, the bellows may also be made of a metallic material. Multiple bellows may be provided. Optionally, at least the threaded spindle is placed completely within the bellows. The clamping element may protrude from the bellows. With the aid of the bellows, particles possibly formed during the rotation of the threaded spindle with respect to the clamping element may be retained within the bellows.

According to an embodiment, the clamping element is operatively connected to the drive element with the aid of an eccentric element.

In this case, an axis of rotation of the eccentric element is oriented perpendicular to a direction of movement of the clamping element, such as of a clamping portion of the clamping element. For example, the clamping element has a cylindrical or pot-shaped receiving portion into which the eccentric element protrudes. On the inside, the receiving portion may comprise a contact region which projects radially into the receiving portion and which always makes contact with the eccentric element. If the eccentric element rotates about its axis of rotation, the latter moves the contact region and hence also the clamping element. The clamping element may be mounted on a fixed reference frame with the aid of leaf spring elements. The fixed reference frame may be connected to the manipulator frame or be part of the manipulator frame.

According to an embodiment, the clamping element is coupled to the eccentric element with the aid of a spring element, wherein the spring element prestresses the clamping element against the eccentric element.

In particular, this means that the spring element is extended when the eccentric element is moved from a non-deflected state into a deflected state. For example, the spring element is a tension spring. The spring element may be a cylindrical spring. The spring element can be coupled to the eccentric element, such as on the rotational shaft of the latter. Furthermore, the spring element can be joined to the receiving portion of the clamping element on the inside. Hence the spring element can be placed within the receiving portion of the clamping element. In cross section, the eccentric element may have an oval or ovoid geometry.

According to an embodiment, the clamping assembly comprises a clamping element and a hydraulic cylinder for displacing the clamping element in order to switch the clamping assembly from the closed state to the open state and vice versa.

For example, the clamping element is displaced linearly, i.e. along a straight line. The hydraulic cylinder may be a single-acting or double-acting cylinder. In this case, “single-acting” means that the hydraulic cylinder can be extended, for example with the aid of a corresponding hydraulic pressure of a hydraulic fluid received in the hydraulic cylinder, with the hydraulic cylinder being retracted purely with the aid of gravity, for example. Accordingly, “double-acting” means that the hydraulic cylinder can be both extended and retracted with the aid of the hydraulic pressure. In the case of a single-acting hydraulic cylinder, the latter may be assigned a spring element which is suitable for prestressing a piston of the hydraulic cylinder. However, the hydraulic cylinder may also be suitable for tilting the clamping element in order to switch the clamping assembly from the closed state to the open state and vice versa. In this case, the clamping element is pivoted about an axis of rotation. For example, the hydraulic cylinder comprises a housing in which the piston that is coupled to the clamping element is mounted in linearly movable fashion. The housing can be filled with the aforementioned hydraulic fluid, which is configured to move the piston in the housing. The housing may be connected to a hydraulic motor, for example in the form of a pump, with the aid of hydraulic lines.

According to an embodiment, the clamping element is mounted on a fixed reference frame with the aid of elastically deformable leaf spring elements.

As mentioned previously, the fixed reference frame may be connected to the manipulator frame or be part of the manipulator frame. In the present case, “fixed reference frame” means that, in particular, the fixed reference frame is fixed vis-à-vis the clamping element. The elastically deformable leaf spring elements act as flexures and allow a linear movement of the clamping element in the direction of the respective mount strut or away from the latter.

According to an embodiment, the clamping element is mounted on a frame with the aid of first leaf spring elements, wherein the frame is mounted on the fixed reference frame with the aid of second leaf spring elements.

In this case, a set of first leaf spring elements and a set of second leaf spring elements can be provided. The first leaf spring elements can couple the clamping element to the frame, which is mounted on the fixed reference frame by way of the second leaf spring elements. Furthermore, the frame can be coupled to a further frame by way of a further leaf spring element, and the further frame is likewise operatively connected to the fixed reference frame. Additionally, the clamping element can also be coupled to the further frame with the aid of a further leaf spring element.

According to an embodiment, the optical assembly comprises a mount with a mount strut which is supported on the manipulator frame, wherein in the closed state of the clamping assembly, the clamping element applies a clamping force to the mount strut.

In general, there can be any desired number of mount struts. Optionally, exactly three mount struts are provided. The mount struts may be arranged offset from one another at an angle of 120°. Each clamping assembly may be assigned exactly one mount strut. That is to say, three clamping assemblies can be provided. Should no mount struts be provided, the clamping assembly may act directly on the optical element, as mentioned previously. In this case, the aforementioned contact element may be directly adhesively bonded to the optical element. However, decoupling is taken into account so that no parasitic forces are introduced into the optical element. In the present case, the mount struts being “supported” on the manipulator frame may mean that, in particular, the weight of the optical assembly is introduced into the manipulator frame with the aid of the mount struts. In particular, “support” may also merely mean that the mount struts, in particular arm portions of the mount struts, are in contact with the manipulator frame, for example a frame strut of the manipulator frame. In the optimum case, this is only a point contact in order to prevent a statically overconstrained system. Should the stresses be too high for point contacts, surface contacts or line contacts, for example, may also be provided.

Furthermore, a projection exposure apparatus having such an optical system is proposed.

The optical system can be a projection optics unit of the projection exposure apparatus. However, the optical system may also be an illumination system. The projection exposure apparatus can be an EUV lithography apparatus. EUV stands for “extreme ultraviolet” and denotes a wavelength of the operating light of between 0.1 nm and 30 nm. The projection exposure apparatus can also be a DUV lithography apparatus. DUV stands for “deep ultraviolet” and denotes a wavelength of the operating light of between 30 nm and 250 nm.

“A(n)/one” should not necessarily be understood as a restriction to exactly one element in the present case. Rather, multiple elements, for example two, three or more, may also be provided. Any other numeral used here should also not be understood as a restriction to exactly the stated number of elements. Rather, unless indicated otherwise, numerical deviations upward and downward are possible.

The embodiments and features described for the optical system apply correspondingly to the proposed projection exposure apparatus, and vice versa.

Further possible implementations of the disclosure also encompass not explicitly mentioned combinations of features or embodiments that are described above or hereinafter with respect to the exemplary embodiments. A person skilled in the art will also add individual aspects as improvements or supplementations to the respective basic form of the disclosure.

Further configurations and aspects of the disclosure are the subject of the dependent claims and of the exemplary embodiments of the disclosure that are described hereinafter. The disclosure will be explained in more detail hereinafter on the basis of certain embodiments with reference to the appended figures.

### BRIEF DESCRIPTION OF THE DRAWINGS

FIG. 1 shows a schematic meridional section of an embodiment of a projection exposure apparatus for EUV projection lithography;

FIG. 2 shows a schematic view of an embodiment of a projection exposure apparatus for DUV projection lithography;

FIG. 3 shows a schematic plan view of an embodiment of an optical assembly for the projection exposure apparatus according to FIG. 1 or according to FIG. 2;

FIG. 4 shows a schematic back view of the optical assembly according to FIG. 3;

FIG. 5 shows a schematic view of an optical system for the projection exposure apparatus according to FIG. 1 or according to FIG. 2;

FIG. 6 shows a further schematic view of the optical system according to FIG. 5;

FIG. 7 shows a schematic sectional view of an embodiment of a clamping assembly for the optical system according to FIG. 5;

FIG. 8 shows a further schematic sectional view of the clamping assembly according to FIG. 7;

FIG. 9 shows a schematic bottom view of the clamping assembly according to FIG. 7;

FIG. 10 shows a schematic plan view of the clamping assembly according to FIG. 7;

FIG. 11 shows a schematic sectional view of a further embodiment of a clamping assembly for the optical system according to FIG. 5;

FIG. 12 shows a further schematic sectional view of the clamping assembly according to FIG. 11;

FIG. 13 shows a schematic sectional view of a further embodiment of a clamping assembly for the optical system according to FIG. 5;

FIG. 14 shows a further schematic sectional view of the clamping assembly according to FIG. 13;

FIG. 15 shows a schematic sectional view of a further embodiment of a clamping assembly for the optical system according to FIG. 5;

FIG. 16 shows a further schematic sectional view of the clamping assembly according to FIG. 15;

FIG. 17 shows a schematic sectional view of a further embodiment of a clamping assembly for the optical system according to FIG. 5;

FIG. 18 shows a further schematic sectional view of the clamping assembly according to FIG. 17;

FIG. 19 shows a schematic sectional view of a further embodiment of a clamping assembly for the optical system according to FIG. 5; and

FIG. 20 shows a schematic sectional view of a further embodiment of a clamping assembly for the optical system according to FIG. 5.

### DETAILED DESCRIPTION

In the figures, identical or functionally identical elements have been provided with the same reference signs, unless indicated otherwise. It should also be noted that the illustrations in the figures are not necessarily true to scale.

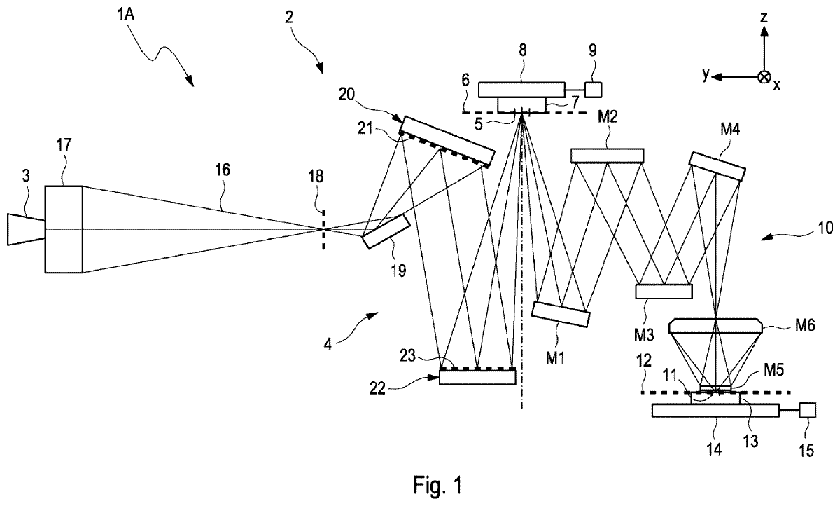

FIG. 1 shows one embodiment of a projection exposure apparatus 1A (lithography apparatus), for example an EUV lithography apparatus. An embodiment of an illumination system 2 of the projection exposure apparatus 1A has, in addition to a light or radiation source 3, an illumination optics unit 4 for illuminating an object field 5 in an object plane 6. In an alternative embodiment, the light source 3 may also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

FIG. 1 depicts, for explanation purposes, a Cartesian coordinate system with an x-direction x, a y-direction y and a z-direction z. The x-direction x runs perpendicularly into the plane of the drawing. The y-direction y runs horizontally, and the z-direction z runs vertically. The scanning direction runs in the y-direction y in FIG. 1. The z-direction z runs perpendicularly to the object plane 6.

The projection exposure apparatus 1A comprises a projection optics unit 10. The projection optics unit 10 is used to image the object field 5 into an image field 11 in an image plane 12. The image plane 12 extends parallel to the object plane 6. Alternatively, an angle between the object plane 6 and the image plane 12 that differs from 0° is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, for example in the y-direction y. The displacement, firstly, of the reticle 7 by way of the reticle displacement drive 9 and, secondly, of the wafer 13 by way of the wafer displacement drive 15 may be implemented so as to be synchronized with one another.

The light source 3 is an EUV radiation source. The light source 3 emits EUV radiation 16, which is also referred to below as used radiation, illumination radiation or illumination light. The used radiation 16 has for example a wavelength in the range between 5 nm and 30 nm. The light source 3 may be a plasma source, for example an LPP (laser produced plasma) source or a GDPP (gas discharge produced plasma) source. It may also be a synchrotron-based radiation source. The light source 3 may be a free electron laser (FEL).

The illumination radiation 16 emanating from the light source 3 is focused by a collector 17. The collector 17 may be a collector having one or more ellipsoidal and/or hyperboloidal reflection surfaces. The illumination radiation 16 may be incident on the at least one reflection surface of the collector 17 with grazing incidence (GI), i.e. at angles of incidence of greater than 45°, or with normal incidence (NI), i.e. at angles of incidence of less than 45°. The collector 17 may be structured and/or coated, firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 can represent a separation between a radiation source module, comprising the light source 3 and the collector 17, and the illumination optics unit 4.

The illumination optics unit 4 comprises a deflection mirror 19 and, arranged downstream thereof in the beam path, a first facet mirror 20. The deflection mirror 19 may be a planar deflection mirror or alternatively a mirror with a beam-influencing effect that goes beyond the pure deflection effect. In addition to that or in an alternative, the deflection mirror 19 may be embodied as a spectral filter that separates a used light wavelength of the illumination radiation 16 from extraneous light of a wavelength deviating therefrom. If the first facet mirror 20 is arranged in a plane of the illumination optics unit 4 that is optically conjugate to the object plane 6 as a field plane, it is also referred to as a field facet mirror. The first facet mirror 20 comprises a multiplicity of individual first facets 21, which can also be referred to as field facets. Only some of these first facets 21 are illustrated in FIG. 1 by way of example.

The first facets 21 may be embodied as macroscopic facets, for example as rectangular facets or as facets with an arcuate or partly circular edge contour. The first facets 21 may take the form of planar facets or alternatively convexly or concavely curved facets.

As is known from DE 10 2008 009 600 A1, for example, the first facets 21 themselves may each also be composed of a multiplicity of individual mirrors, for example a multiplicity of micromirrors. The first facet mirror 20 may for example take the form of a microelectromechanical system (MEMS system). For details, reference is made to DE 10 2008 009 600 A1.

The illumination radiation 16 travels horizontally, i.e. in the y-direction y, between the collector 17 and the deflection mirror 19.

In the beam path of the illumination optics unit 4, a second facet mirror 22 is arranged downstream of the first facet mirror 20. If the second facet mirror 22 is arranged in a pupil plane of the illumination optics unit 4, it is also referred to as a pupil facet mirror. The second facet mirror 22 may also be arranged at a distance from a pupil plane of the illumination optics unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which can for example have a round, rectangular or else hexagonal boundary, or may alternatively be facets composed of micromirrors. In this regard, reference is likewise made to DE 10 2008 009 600 A1.

The second facets 23 may have planar or alternatively convexly or concavely curved reflection surfaces.

The illumination optics unit 4 thus forms a doubly faceted system. This fundamental principle is also referred to as a fly's eye integrator.

It may be desirable to arrange the second facet mirror 22 not exactly in a plane that is optically conjugate to a pupil plane of the projection optics unit 10. For example, the second facet mirror 22 can be arranged so as to be tilted in relation to a pupil plane of the projection optics unit 10, as described for example in DE 10 2017 220 586 A1.

The second facet mirror 22 is used to image the individual first facets 21 into the object field 5. The second facet mirror 22 is the last beam-shaping mirror or else actually the last mirror for the illumination radiation 16 in the beam path upstream of the object field 5.

In a further embodiment (not illustrated) of the illumination optics unit 4, a transfer optics unit contributing for example to the imaging of the first facets 21 into the object field 5 may be arranged in the beam path between the second facet mirror 22 and the object field 5. The transfer optics unit may have exactly one mirror, or alternatively two or more mirrors arranged one behind another in the beam path of the illumination optics unit 4. The transfer optics unit may for example comprise one or two normal-incidence mirrors (NI mirrors) and/or one or two grazing-incidence mirrors (GI mirrors).

In the embodiment shown in FIG. 1, the illumination optics unit 4 has exactly three mirrors downstream of the collector 17, specifically the deflection mirror 19, the first facet mirror 20 and the second facet mirror 22.

In a further embodiment of the illumination optics unit 4, the deflection mirror 19 can also be omitted, and so the illumination optics unit 4 may have exactly two mirrors downstream of the collector 17 in that case, specifically the first facet mirror 20 and the second facet mirror 22.

The imaging of the first facets 21 into the object plane 6 via the second facets 23 or using the second facets 23 and a transfer optics unit is regularly only approximate imaging.

The projection optics unit 10 comprises a plurality of mirrors Mi, which are consecutively numbered in accordance with their arrangement in the beam path of the projection exposure apparatus 1A.

In the example illustrated in FIG. 1, the projection optics unit 10 comprises six mirrors M1 to M6. Alternatives with four, eight, ten, twelve or any other number of mirrors Mi are likewise possible. The projection optics unit 10 is a doubly obscured optical unit. The penultimate mirror M5 and the last mirror M6 each have a passage opening for the illumination radiation 16. The projection optics unit 10 has an image-side numerical aperture that is greater than 0.5 and may also be greater than 0.6 and may be, for example, 0.7 or 0.75.

Reflection surfaces of the mirrors Mi may take the form of free-form surfaces without an axis of rotational symmetry. Alternatively, the reflection surfaces of the mirrors Mi may be designed as aspheric surfaces with exactly one axis of rotational symmetry of the reflection surface shape. Just like the mirrors of the illumination optics unit 4, the mirrors Mi may have highly reflective coatings for the illumination radiation 16. These coatings may be in the form of multilayer coatings, for example with alternating layers of molybdenum and silicon.

The projection optics unit 10 has a large object-image shift in the y-direction y between a y-coordinate of a center of the object field 5 and a y-coordinate of the center of the image field 11. This object-image shift in the y-direction y can be of approximately the same magnitude as a z-distance between the object plane 6 and the image plane 12.

The projection optics unit 10 may for example have an anamorphic form. It has for example different imaging scales βx, βy in the x-and y-directions x, y. The two imaging scales βx, βy of the projection optics unit 10 can be (βx, βy)=(+/−0.25, +/−0.125). A positive imaging scale β means imaging without image inversion. A negative sign for the imaging scale β means imaging with image inversion.

The projection optics unit 10 consequently leads to a reduction in size with a ratio of 4:1 in the x-direction x, i.e. in a direction perpendicular to the scanning direction.

The projection optics unit 10 leads to a reduction in size of 8:1 in the y-direction y, i.e. in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 can be the same or can differ, depending on the embodiment of the projection optics unit 10. Examples of projection optics units with different numbers of such intermediate images in the x-direction x and the y-direction y are known from US 2018/0074303 A1.

In each case one of the second facets 23 is assigned to exactly one of the first facets 21 in order to form a respective illumination channel for illuminating the object field 5. For example, this may result in illumination according to the Köhler principle. The far field is decomposed into a multiplicity of object fields 5 using the first facets 21. The first facets 21 generate a plurality of images of the intermediate focus on the second facets 23 respectively assigned to them.

The first facets 21 are each imaged onto the reticle 7 by an assigned second facet 23 with images overlaid over one another for the purpose of illuminating the object field 5. The illumination of the object field 5 is for example as homogeneous as possible. It can have a uniformity error of less than 2%. Field uniformity may be achieved by overlaying different illumination channels.

An arrangement of the second facets 23 may geometrically define the illumination of the entrance pupil of the projection optics unit 10. The intensity distribution in the entrance pupil of the projection optics unit 10 may be set by selecting the illumination channels, for example the subset of the second facets 23 that guide light. This intensity distribution is also referred to as illumination setting or illumination pupil filling.

A likewise preferred pupil uniformity in the region of portions of an illumination pupil of the illumination optics unit 4 that are illuminated in a defined manner may be achieved by a redistribution of the illumination channels.

Further aspects and details of the illumination of the object field 5 and for example of the entrance pupil of the projection optics unit 10 are described below.

The projection optics unit 10 may have for example a homocentric entrance pupil. The latter may be accessible. It may also be inaccessible.

The entrance pupil of the projection optics unit 10 regularly cannot be exactly illuminated with the second facet mirror 22. In the case of imaging by the projection optics unit 10 which telecentrically images the center of the second facet mirror 22 onto the wafer 13, the aperture rays often do not intersect at a single point. However, it is possible to find an area in which the spacing of the aperture rays that is determined in pairs becomes minimal. This area is the entrance pupil or an area conjugate thereto in real space. For example, this area exhibits a finite curvature.

It may be the case that the projection optics unit 10 has different poses of the entrance pupil for the tangential beam path and for the sagittal beam path. In this case, an imaging element, for example an optical component of the transfer optics unit, should be provided between the second facet mirror 22 and the reticle 7. With the aid of this optical element, the different poses of the tangential entrance pupil and the sagittal entrance pupil may be taken into account.

In the arrangement of the components of the illumination optics unit 4 illustrated in FIG. 1, the second facet mirror 22 is arranged in an area conjugate to the entrance pupil of the projection optics unit 10. The first facet mirror 20 is arranged so as to be tilted with respect to the object plane 6. The first facet mirror 20 is arranged so as to be tilted with respect to an arrangement plane defined by the deflection mirror 19. The first facet mirror 20 is arranged so as to be tilted with respect to an arrangement plane defined by the second facet mirror 22.

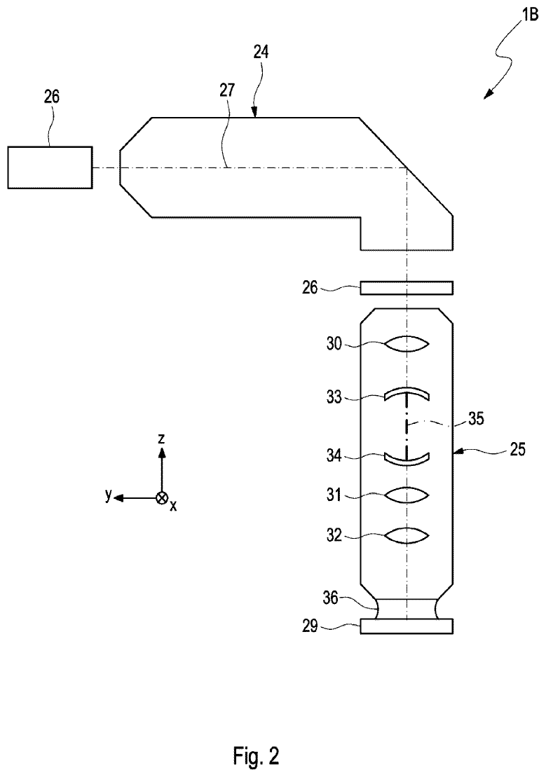

FIG. 2 shows a schematic view of a projection exposure apparatus 1B, for example of a DUV lithography apparatus, comprising a beam shaping and illumination system 24 (also referred to here as “illumination optics unit”) and a projection optics unit 25 (also referred to here as “projection lens”). In this case, DUV stands for “deep ultraviolet” and denotes a wavelength of the operating light of between 30 nm and 250 nm.

The beam shaping and illumination system 24 and the projection optics unit 25 each can be arranged in a vacuum housing (not shown). Each vacuum housing is evacuated with the aid of an evacuation device (not illustrated). The vacuum housings are surrounded by a machine room (not illustrated), in which drive devices for mechanically moving or setting optical elements can be provided. Furthermore, electrical controllers and the like can also be arranged in the machine room.

The projection exposure apparatus 1B comprises a light source 26. For example, an ArF excimer laser that emits radiation 27 in the DUV range, at for example 193 nm, may be provided as the light source 6. In the beam shaping and illumination system 24, the radiation 27 is focused, and a desired operating wavelength (operating light) is filtered out from the radiation 27. The beam shaping and illumination system 24 may have optical elements which are not illustrated, for example mirrors or lens elements.

After passing through the beam shaping and illumination system 24, the radiation 27 is guided onto a photomask (reticle) 28. The photomask 28 is formed as a transmissive optical element and can be arranged outside the beam shaping and illumination system 24 and the projection optics unit 25. The photomask 28 has a structure which is imaged onto a wafer 29 in reduced form via the projection optics unit 25.

The projection optics unit 25 has a plurality of lens elements 30, 31, 32 and/or mirrors 33, 34 for imaging the photomask 28 onto the wafer 29. In this case, individual lens elements 30, 31, 32 and/or mirrors 33, 34 of the projection optics unit 25 may be arranged symmetrically relative to an optical axis 35 of the projection optics unit 25. It should be noted that the number of lens elements 30, 31, 32 and mirrors 33, 34 shown here is purely by way of example and is not restricted to the number shown. A greater or lesser number of lens elements 30, 31, 32 and/or mirrors 33, 34 can also be provided.

An air gap between a last lens element (not shown) and the wafer 29 can be replaced by a liquid medium 36 which has a refractive index of >1. The liquid medium 36 can be high-purity water, for example. Such a construction is also referred to as immersion lithography and has an increased photolithographic resolution. The medium 36 may also be referred to as an immersion liquid.

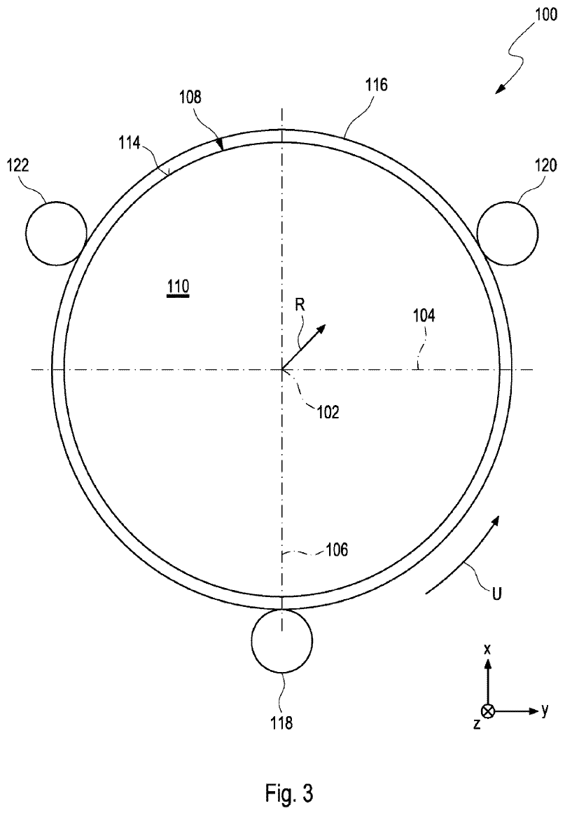

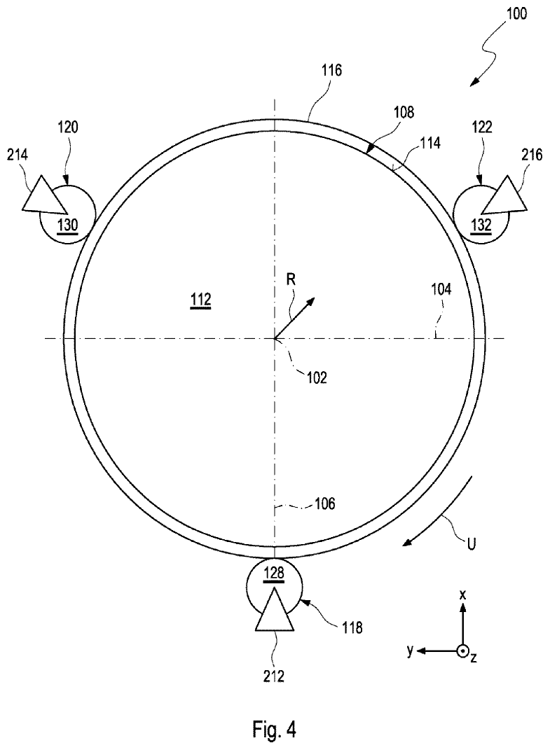

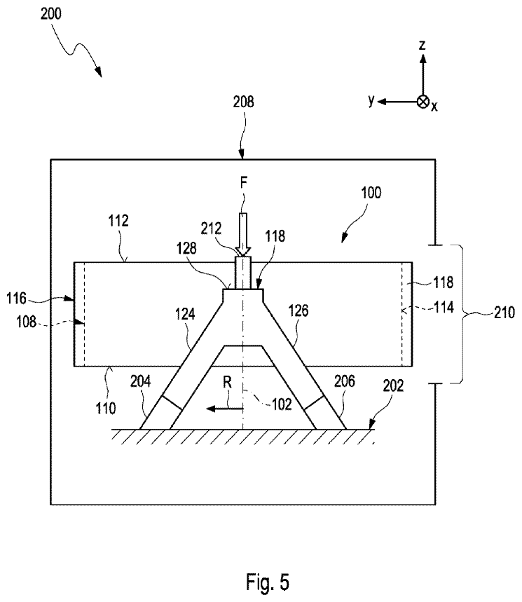

FIG. 3 shows a schematic plan view of an embodiment of an optical assembly 100 for the projection exposure apparatus 1A, 1B. FIG. 4 shows a schematic back view of the optical assembly 100. FIG. 5 shows a schematic view of an optical system 200, which comprises the optical assembly 100. Hereinafter, reference is made to FIGS. 3 to 5 concurrently.

The optical assembly 100 may be part of a projection optics unit 10, 25 as explained above. However, the optical assembly 100 may also be part of an illumination optics unit 4 as explained above or of a beam-shaping and illumination system 24 as explained above. However, it is assumed below that the optical assembly 100 is part of a projection optics unit 10, 25 of this type. The optical assembly 100 is suitable for DUV lithography. However, the optical assembly 100 may also be suitable for EUV lithography.

The optical assembly 100 may be one of the mirrors M1 to M6, 33, 34 or one of the lens elements 30, 31, 32. The optical assembly 100 may accordingly be a mirror or a mirror module or may be referred to as such. The optical assembly 100 may be a mirror assembly or be referred to as such. For example, the optical assembly 100 may be an EUV mirror or a DUV mirror or may be referred to as such. The optical assembly 100 may be assigned the coordinate system comprising the x-direction x, the y-direction y and the z-direction z. The x-direction x may also be referred to as an x-axis, the y-direction y may also be referred to as a y-axis, and the z-direction z may also be referred to as a z-axis.

The optical assembly 100 has an axis of symmetry or central axis 102 which is oriented parallel to the z-direction z or coincides therewith. The optical assembly 100 may be constructed substantially rotationally symmetrically with respect to the central axis 102. The optical assembly 100 is assigned two half axes 104, 106 which intersect the central axis 102. A radial direction R of the optical assembly 100 is oriented perpendicular to the central axis 102 and away from the latter. A circumferential direction U is oriented around the central axis 102.

The optical assembly 100 is swappable. That is to say, the optical assembly 100 may be removed from the projection optics unit 10 explained and inserted again into the latter. Alternatively, the optical assembly 100 may also be replaced by another optical assembly 100. An appropriate swapping tool (not shown) may be provided for swapping the optical assembly 100. The optical assembly 100 can be swapped “in the field”, i.e. directly at the operating location of the projection exposure apparatus 1A, 1B.

The optical assembly 100 comprises an optical element 108. The optical element 108 may be a mirror. The optical element 108 comprises an optically effective surface 110. The optically effective surface 110 is suitable for reflecting illumination radiation 16, for example EUV radiation, during operation of the optical assembly 100. The optically effective surface 110 is a mirror surface. The optically effective surface 110 may be realized with the aid of a coating.

The optical element 108 has a rear side 112 facing away from the optically effective surface 110. The rear side 112 does not have defined surface properties. That is to say for example that the rear side 112 is not a mirror surface and therefore does not have reflective properties either. An outer surface 114 of the optical element 108 is provided between the optically effective surface 110 and the rear side 112. The outer surface 114 may be cylindrical. The outer surface 114 may be constructed rotationally symmetrically with respect to the central axis 102.

In addition to the optical element 108, the optical assembly 100 comprises a mount 116, which carries the optical element 108. The mount 116 is connected to the optical element 108, for example to the outer surface 114. An integral bond may be provided to this end. In integral bonds, the connection partners are held together by atomic or molecular forces. Integral bonds are non-releasable connections that can be separated only by destruction of the connection mechanism(s) and/or the connection partners. An integral bond may be implemented by adhesive bonding, for example. That is to say, the mount 116 may be adhesively bonded to the optical element 108, for example to the outer surface 114.

The mount 116 is a one-piece component, for example one which is materially in one piece. In this case, “one-piece” or “integral” means that, in particular, the mount 116 is not composed of different subordinate components, but rather the mount 116 forms a continuous component. In this case, “materially in one piece” means that, in particular, the mount 116 is produced from the same material throughout. For example, the mount 116 may be produced from copper, aluminum, steel or the like. The mount 116 may be produced with the aid of an additive or generative production method, for example with the aid of a 3D printing method. Furthermore, the mount 116 may also be produced with the aid of an erosion method.

Mount struts 118, 120, 122 are attached to the mount 116. For example, a first mount strut 118, a second mount strut 120 and a third mount strut 122 are provided. The mount struts 118, 120, 122 are known as “A struts” or may be referred to as such. Optionally, precisely three mount struts 118, 120, 122 which are offset by 120° with respect to one another are provided.

The mount struts 118, 120, 122 are securely connected to the mount 116, for example by screwing. For example, each mount strut 118, 120, 122 comprises a housing to which the mount 116 is connected. The mount struts 118, 120, 122 can be identical. Therefore, only the mount strut 118 is discussed below. All statements regarding the mount strut 118 are applicable to the mount struts 120, 122, and vice versa.

As FIG. 5 shows, each mount strut 118 has two arm portions 124, 126. In addition to the optical assembly 100, the optical system 200 comprises a manipulator frame 202. The arm portions 124, 126 are supported on the manipulator frame 202. To this end, six frame struts 204, 206 are provided on the manipulator frame 202, only two of which are shown in FIG. 5. The optical assembly 100 is coupled to the manipulator frame 202 with the aid of the frame struts 204, 206. As mentioned previously, the inner ring 120 is not shown in FIG. 5.

Each mount strut 118, 120, 122 is assigned two of the frame struts 204, 206. That is to say, each mount strut 118, 120, 122 rests against two of these frame struts 204, 206. The optical assembly 100 is mechanically decoupled from the manipulator frame 202 with the aid of the mount struts 118, 120, 122. To this end, each mount strut 118, 120, 122 has joints, for example what are referred to as flexures. Each mount strut 118, 120, 122 has a support surface 128, 130, 132 (FIG. 4). In the orientation of FIG. 5, the support surfaces 128, 130, 132 are oriented upward.

The optical assembly 100 is received within a housing 208 of the optical system 200. The housing 208 may be a mirror housing or may be referred to as such. To swap the optical assembly 100, the latter has to be removed from the housing 208. A new optical assembly 100 subsequently has to be inserted into the housing 208. The optical assembly 100 is swapped through an opening 210 provided in the housing 208. The opening 210 is closable. For this purpose, a suitable cover is provided.

The optical system 200 comprises multiple clamping assemblies 212, 214, 216 (FIG. 4). For example, exactly three clamping assemblies 212, 214, 216 are provided. Optionally, a first clamping assembly 212, a second clamping assembly 214 and a third clamping assembly 216 are provided. Each mount strut 118, 120, 122 is assigned a clamping assembly 212, 214, 216. The clamping assemblies 212, 214, 216 are depicted only very abstractly in FIGS. 4 and 5. The precise structural design of the clamping assemblies 212, 214, 216 will be explained below.

The clamping assemblies 212, 214, 216 are offset from one another by 120°. The clamping assemblies 212, 214, 216 have different constructions, as will be explained below. At least one of the clamping assemblies 212, 214, 216, for example the clamping assembly 216, may be capable of disassembly such that the latter does not impede the exchange of the optical assembly 100 through the opening 210 in the housing 208.

With the aid of the clamping assemblies 212, 214, 216, it is possible to apply a suitable clamping force F (FIG. 5) to the respective support surface 128, 130, 132 of the mount struts 118, 120, 122 in order to couple the optical assembly 100 to the manipulator frame 202. The respective clamping force F is introduced into the corresponding mount strut 118, 120, 122. Although the mount struts 118, 120, 122 are connected to the mount 116, they are mechanically decoupled from the mount 116 such that the clamping forces F are not introduced into the mount 116, and hence not into the optical element 108, but only into the mount struts 118, 120, 122.

The clamping assemblies 212, 214, 216 are connected to the manipulator frame 202, wherein at least one of the clamping assemblies 212, 214, 216, for example the clamping assembly 216, may be capable of disassembly from the manipulator frame 202. A plug-in and/or screw connection may be provided to this end and enable simple assembly and disassembly of the clamping assembly 216 capable of disassembly.

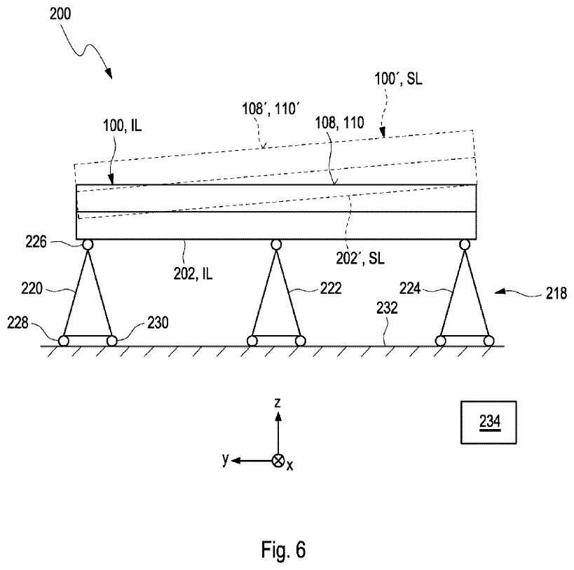

FIG. 6 shows a further view of the optical system 200.

The optical system 200 is depicted only very abstractly in FIG. 6. For example, the mount struts 118, 120, 122 and the clamping assemblies 212, 214, 216, which couple the mount 116 to the manipulator frame 202, are not depicted in FIG. 6. The mount 116 is not shown in FIG. 6 either.

The optical assembly 100, or the optically effective surface 110 of the optical element 108 in the optical assembly 100, has six degrees of freedom, namely three translational degrees of freedom in the first spatial direction or x-direction x, the second spatial direction or y-direction y and the third spatial direction or z-direction z, and three rotational degrees of freedom about the x-direction x, the y-direction y and the z-direction z. This means that a position and an orientation of the optical assembly 100, or of the optically effective surface 110, can be determined or described using the six degrees of freedom.

The “position” of the optical assembly 100, or of the optical effective surface 110, is in particular understood to mean the coordinates thereof or the coordinates of a measurement point provided on the optical assembly 100 with respect to the x-direction x, the y-direction y and the z-direction z. The “orientation” of the optical assembly 100, or of the optically effective surface 110, is understood to mean in particular its tilt with respect to the three directions x, y, z. That is to say, the optical assembly 100, or the optically effective surface 110, may be tilted about the x-direction x, the y-direction y and/or the z-direction z.

This gives the six degrees of freedom for the position and orientation of the optical assembly 100, or of the optically effective surface 110. A “pose” of the optical assembly 100, or of the optically effective surface 110, comprises both its position and its orientation. The term “pose” is accordingly replaceable by the wording “position and orientation”, and vice versa.

FIG. 6 shows an actual pose IL of the optical assembly 100, or of the optical element 108 with the optically effective surface 110, in solid lines and a target pose SL of the optical assembly 100, or of the optical element 108 with the optically effective surface 110, in dashed lines and with the reference signs 100′, 108′110′. An actual pose IL of the manipulator frame 202 coupled to the optical assembly 100 is also depicted using solid lines. A target pose SL of the manipulator frame 202 is depicted using dashed lines and the reference sign 202′.

The optical assembly 100, together with the manipulator frame 202, can be switched from its actual pose IL to the target pose SL, and vice versa. For example, the optical assembly 100, or the optically effective surface 110, meets certain optical specifications or desired properties in the target pose SL which the optical assembly 100, or the optically effective surface 110, does not meet in the actual pose IL.

In order to move the optical assembly 100 from the actual pose IL to the target pose SL, the optical system 200 comprises an adjustment device 218. The adjustment device 218 is configured for adjusting the optical assembly 100. In the present case, an “adjustment” or “alignment” should be understood to mean, in particular, a change in the pose of the optical assembly 100. When the pose of the optical assembly 100 is changed, the mount struts 118, 120, 122 and the clamping assemblies 212, 214, 216 and the manipulator frame 202 are moved together with the optical assembly 100.

For example, the optical assembly 100 can be switched from the actual pose IL to the target pose SL and vice versa with the aid of the adjustment device 218. The optical assembly 100 may thus be adjusted or aligned with the aid of the adjustment device 218 in all the six aforementioned degrees of freedom. The adjustment device 218 is what is known as a hexapod or may be referred to as such.

The adjustment device 218 comprises multiple actuators 220, 222, 224, which are shown only very schematically in FIG. 6. The actuators 220, 222, 224 may also be referred to as actuator systems or actuating elements. The actuators 220, 222, 224 may be what are known as bipods or may be referred to as such. Optionally, exactly three actuators 220, 222, 224 are provided, arranged in a manner distributed offset by 120° around the central axis 102. The actuators 220, 222, 224 can have identical designs.

The actuators 220, 222, 224 are joined to the manipulator frame 202 via joining points 226, only one of which has been provided with a reference sign in FIG. 6. For example, an adhesive connection or a screwed connection may be provided at each of the joining points 226. There can be exactly three joining points 226, with each joining point 226 being assigned an actuator 220, 222, 224. The optical assembly 100 in turn is operatively connected to the manipulator frame 202 with the aid of the mount struts 118, 120, 122 and the clamping assemblies 212, 214, 216.

Further, each actuator 220, 222, 224 is coupled to a load-bearing structure 232 via two joining points 228, 230, only two of which have been provided with a reference sign in FIG. 6. The load-bearing structure 232 can be a force frame or any other immovable structure. The load-bearing structure 232 may also be called a fixed reference frame.

The actuators 220, 222, 224 can be used to move the manipulator frame 202 and the optical assembly 100 with respect to the load-bearing structure 232. Each actuator 220, 222, 224 may be assigned two of the aforementioned degrees of freedom. The three actuators 220, 222, 224 thus make it possible to adjust the optical assembly 100 in all six degrees of freedom.

The actuators 220, 222, 224 can be controlled via an open-loop and closed-loop control unit 234 of the adjustment device 218, in order to adjust the optical assembly 100 or the optical element 108. All the actuators 220, 222, 224 are operatively connected to the open-loop and closed-loop control unit 234, and as a result the open-loop and closed-loop control unit 234 can adjust the optical assembly 100 together with the manipulator frame 202 in all six degrees of freedom by suitably controlling these actuators 220, 222, 224. This may be implemented on the basis of sensor signals from a sensor system (not depicted), which is able to detect the actual pose IL and the target pose SL of the optical assembly 100.

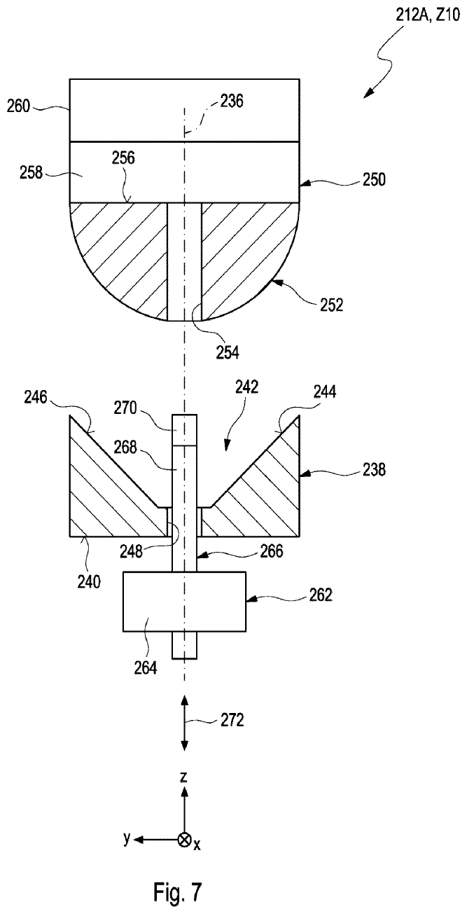

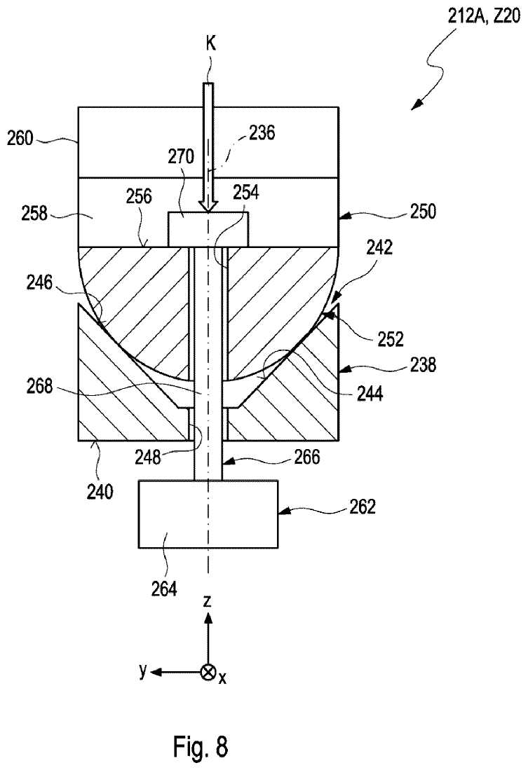

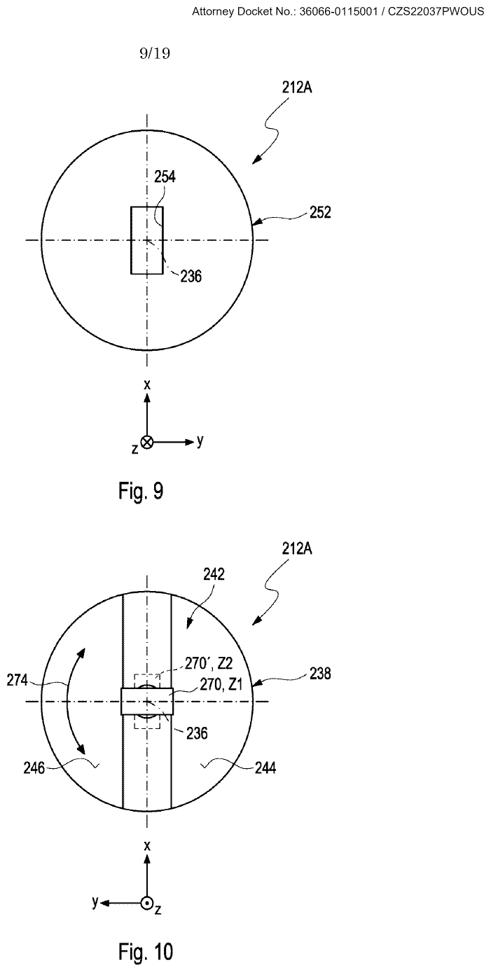

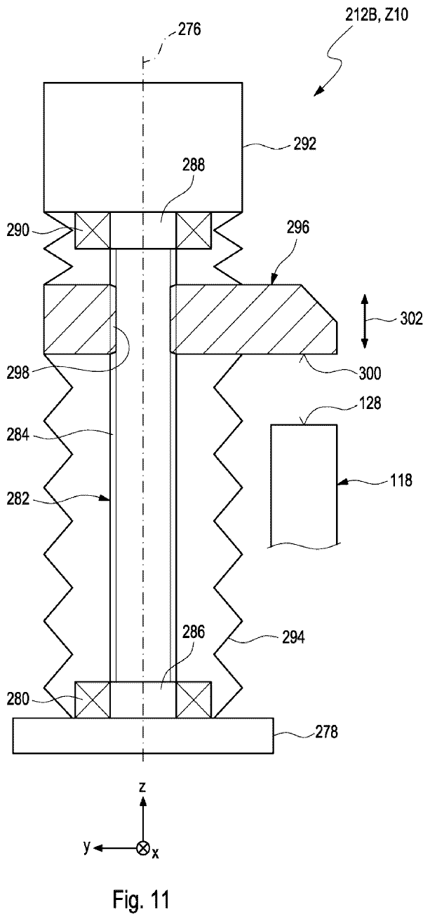

FIG. 7 shows a schematic sectional view of an embodiment of a clamping assembly 212A as mentioned above. FIG. 8 shows a further schematic sectional view of the clamping assembly 212A. FIG. 9 shows a schematic bottom view of the clamping assembly 212A. FIG. 10 shows a schematic plan view of the clamping assembly 212A. Hereinafter, reference is made to FIGS. 7 to 10 concurrently.

The above-described mount struts 118, 120, 122 may be omitted if the clamping assembly 212A is used. The mount 116 is also optional. That is to say, the clamping assembly 212A may be directly joined to the optical element 108. The clamping assembly 212A is assigned a central axis or axis of symmetry 236, in relation to which the clamping assembly 212A may have a substantially rotationally symmetric construction.

The clamping assembly 212A comprises a groove element 238. The groove element 238 may be constructed rotationally symmetrically with respect to the axis of symmetry 236. The groove element 238 comprises a rear side 240, on which the groove element 238 is connected to the manipulator frame 202. Facing away from the rear side 240, a V-shaped groove 242 with two contact surfaces 244, 246 oriented obliquely with respect to one another is provided on the groove element 238. The groove element 238 is perforated by a perforation 248. The perforation 248 may be a bore.

Furthermore, the clamping assembly 212A comprises a contact element 250 which is configured to bear against the contact surfaces 244, 246. The contact element 250 comprises a contact portion 252. The contact portion 252 may be cylindrical or spherical-cap-shaped. In the present case, a “spherical cap” is understood to mean a portion of a sphere. The contact portion 252 can be hemispherical. The contact portion 252 is perforated by a perforation 254. The perforation 254 may be an elongate hole extending in the x-direction x. The contact portion 252 comprises a rear side 256.

In addition to the contact portion 252, the contact element 250 comprises a receiving portion 258. With its receiving portion 258, the contact element 250 is joined to a decoupling element 260. The decoupling element 260 serves for mechanically decoupling the contact element 250 from the optical element 108. The decoupling element 260 may comprise a cardan joint and/or leaf springs.

The decoupling element 260 may be connected, for example adhesively bonded, to the rear side 112 of the optical element 108. However, the decoupling element 260 may also be joined to the optical element 108 on its front side, for example next to the optically effective surface 110.

The clamping assembly 212A furthermore comprises a locking unit 262, with the aid of which the groove element 238 can be connected to the contact element 250. The locking unit 262 comprises a drive element 264. The drive element 264 may comprise a hydraulic drive, a pneumatic drive, a piezo element and/or an electric motor. The drive element 264 may generate a linear movement along the axis of symmetry 236 and a rotational movement about the axis of symmetry 236.

The drive element 264 drives a locking element 266. The locking element 266 comprises a shaft portion 268 which is coupled to and driven by the drive element 264. The shaft portion 268 is guided through the perforation 248 in the groove element 238. The shaft portion 268 may have a circular cross section. A head portion 270 is provided at one end of the shaft portion 268. The head portion 270 has a cuboid geometry. The locking element 266 thus has a hammer-shaped geometry.

The locking element 266 is driven by the drive element 264. The drive element 264 enables an upward and downward movement of the locking element 266 along the axis of symmetry 236, as indicated in FIG. 7 with the aid of a double-headed arrow 272. Furthermore, the drive element 264 also enables a rotation of the locking element 266 about the axis of symmetry 236, as indicated in FIG. 10 with the aid of a double-headed arrow 274.

For example, the drive element 264 may be configured to move the locking element 266 through 90° from a locked state Z1, in which the head portion 270 cannot be guided through the perforation 254 in the contact element 250, into an unlocked state Z2, in which the head portion 270 can be guided through the perforation 254. In the unlocked state Z2, the head portion 270 is depicted using dashed lines in FIG. 10 and provided with reference sign 270′.

The clamping assembly 212A may be switched from an open state Z10 shown in FIG. 7 to a closed state Z20 shown in FIG. 8, and vice versa. In order to switch the clamping assembly 212A from the open state Z10 to the closed state Z20, the drive element 264 rotates the locking element 266 into the unlocked state Z2 and extends the latter so far along the axis of symmetry 236 that the locking element 266 can be guided through the perforation 254 in the contact element 250.

The contact portion 252 is placed on the contact surfaces 244, 246 of the groove element 238, wherein the locking element 266, which is in the unlocked state Z2, is threaded into the perforation 254. When the contact portion 252 rests on the contact surfaces 244, 246 and the head portion 270 is located within the receiving portion 258, the locking element 266 is rotated and switched into the locked state Z1.

Furthermore, the head portion 270 arranged within the receiving portion 258 is pulled in the direction of the rear side 256 of the contact portion 252, and so the head portion 270 engages behind the contact portion 252 and bears against the rear side 256. The head portion 270 now applies a suitable clamping force K to the contact element 250.

Omitting the mount struts 118, 120, 122 enables a simple construction and facilitates the optical assembly 100 swap. Both a swapping procedure and an adjustment of the optical assembly 100 can be improved both with respect to the work outlay and with respect to the time outlay. The downtime of the projection exposure apparatus 1A, 1B during the swap of the optical assembly 100 can be significantly reduced. What are known as surface figure deformations (SFDs) are reduced as a result of the decoupling element 260 being adhesively bonded to the optical element 108 and as a result of the decoupling element 260 being provided.

The locking element 266 can be moved when the optical assembly 100 is already located within the housing 208. Hence, the locking element 266 can be actuated remotely within the housing 208. It is possible to dispense with a tool for switching the clamping assembly 212A from the open state Z10 into the closed state Z20, and vice versa, and dispense with direct manipulation of the clamping assembly 212A.

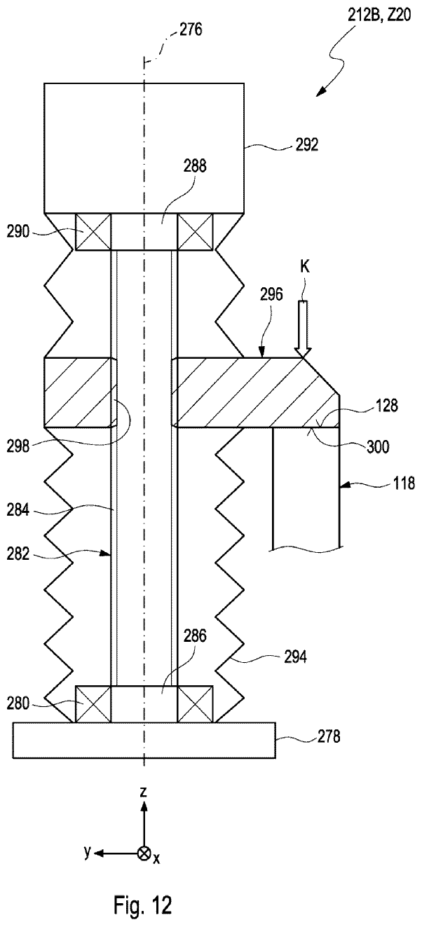

FIG. 11 shows a schematic sectional view of a further embodiment of a clamping assembly 212B. FIG. 12 shows a further schematic sectional view of the clamping assembly 212B. Hereinafter, reference is made to FIGS. 11 and 12 concurrently.

The clamping assembly 212B comprises a central axis or axis of symmetry 276, in relation to which the clamping assembly 212B may have a substantially rotationally symmetric construction. The clamping assembly 212B comprises a base element 278, which may be securely connected, for example screwed, to the manipulator frame 202. The base element 278 may have a planar or frame-shaped embodiment. The base element 278 may be part of a housing (not shown) of the clamping assembly 212B.

A threaded spindle 282 is mounted in a manner rotatable about the axis of symmetry 276 on the base element 278 with the aid of a bearing 280 which can be a rolling bearing or a plain bearing. The threaded spindle 282 comprises a male thread 284. The threaded spindle 282 comprises a first end portion 286 on which the bearing 280 is provided. The first end portion 286 faces the manipulator frame 202. A second end portion 288 of the threaded spindle 282 faces away from the manipulator frame 202.

On the second end portion 288, the threaded spindle 282 comprises a further bearing 290, which may be a rolling bearing or a plain bearing. The bearing 290 may be received in the aforementioned housing of the clamping assembly 212B. The threaded spindle 282 is thus mounted so as to be rotatable about the axis of symmetry 276 with the aid of the bearings 280, 290.

The clamping assembly 212B comprises a drive element 292 which is coupled to the threaded spindle 282 in order to put the latter into rotation about the axis of symmetry 276. The drive element 292 may be an electric motor. The drive element 292 is placed adjacent to the bearing 290. Hence the drive element 292 is operatively connected to the threaded spindle 282 at the second end portion 288. In this case, the drive element 292 may be received in the aforementioned housing of the clamping assembly 212B in a manner secured against rotation.

The threaded spindle 282 is received in a bellows 294. The bellows 294 retains particles possibly formed during the rotation of the threaded spindle 282. The bellows 294 is compressible and extendable along the axis of symmetry 276. The bellows 294 may be made of rubber or of metal.

The threaded spindle 282 carries a clamping element 296. The clamping element 296 may be cuboid. The clamping element 296 comprises a threaded bore 298 through which the threaded spindle 282 is guided. Furthermore, the clamping element 296 comprises a contact area surface 300 which is configured to bear against the support surface 128 of the mount strut 118.

Rotation of the threaded spindle 282 with the aid of the drive element 292 allows the clamping element 296 to be moved upward or downward in the orientation of FIG. 11, as indicated with the aid of a double-headed arrow 302.

The clamping assembly 212B may be switched from an open state Z10 shown in FIG. 11 to a closed state Z20 shown in FIG. 12, and vice versa. The drive element 292 rotates the threaded spindle 282 in order to switch the clamping assembly 212B from the open state Z10 into the closed state Z20.

The clamping element 296 then moves downward in the orientation of FIGS. 11 and 12 until the contact surface 300 of the clamping element 296 bears against the support surface 128 of the mount strut 118. The clamping element 296 then applies a clamping force K to the mount strut 118. The clamping force K can be set or changed with the aid of the drive element 292.

The clamping assembly 212B simplifies the clamping of the optical assembly 100. In this case, the drive element 292 may put the threaded spindle 282 in rotation about the axis of symmetry 276 electrically, hydraulically, pneumatically or with the aid of a piezo element. Switching the clamping assembly 212B from the open state Z10 to the closed state Z20 may be remotely controlled from outside the housing 208. Direct or manual opening or closing of the clamping assembly 212B is dispensable.

The threaded spindle 282 and/or the drive element 292 may be assigned sensors, for example torque sensors or force sensors, which allow a calibration of the drive element 292. The clamping force K may then be set by way of the motor current and/or the motor voltage of the drive element 292. This enables direct control of the clamping force K. The provision of the bellows 294 makes the clamping assembly 212B cleanroom-compatible since the bellows 294 retains particles.

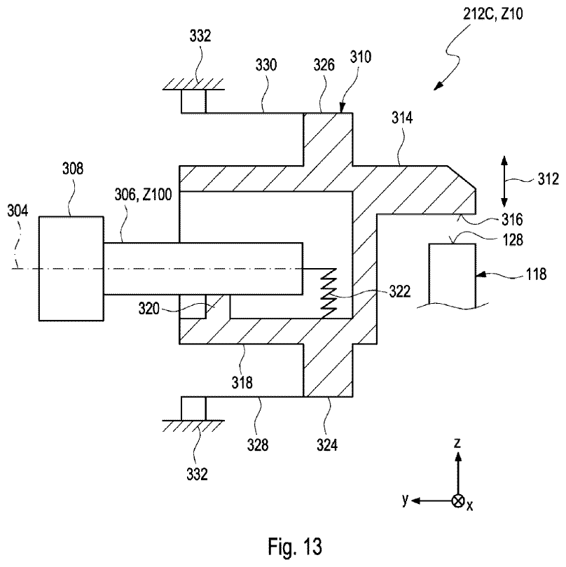

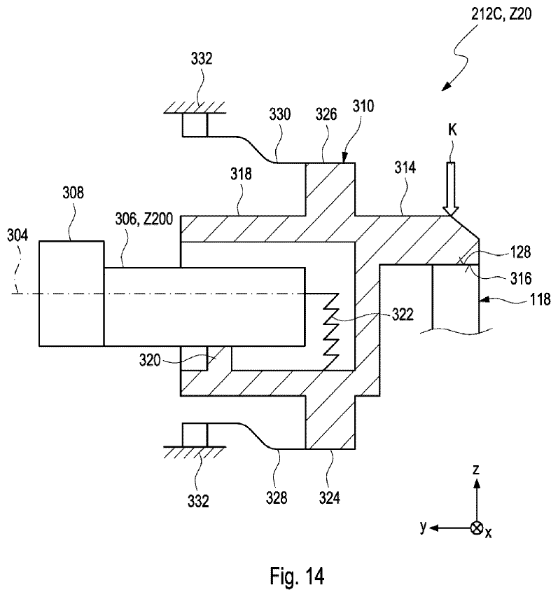

FIG. 13 shows a schematic sectional view of a further embodiment of a clamping assembly 212C. FIG. 14 shows a further schematic sectional view of the clamping assembly 212C. Hereinafter, reference is made to FIGS. 13 and 14 concurrently.

The clamping assembly 212C comprises an eccentric element 306 which is rotatable about an axis of rotation 304. In cross section, the eccentric element 306 may have an ovoid or oval geometry. The eccentric element 306 is switched from a non-deflected state Z100, shown in FIG. 13, to a deflected state Z200, shown in FIG. 14, and vice versa with the aid of a drive element 308. To this end, the drive element 308 rotates the eccentric element 306 about the axis of rotation 304.

The drive element 308 may comprise a gearing. Furthermore, the drive element 308 may comprise a hydraulic, pneumatic or electric drive. Furthermore, the drive element 308 may also comprise a piezo drive. The drive element 308 may be mounted on the manipulator frame 202 or on a housing of the clamping assembly 212C such that the drive element 308 is stationary.

The clamping assembly 212C also comprises a clamping element 310, which interacts with the eccentric element 306 in order to move the clamping element 310 upward and downward in the orientation of FIGS. 13 and 13, as indicated with the aid of a double-headed arrow 312 in FIG. 13. The clamping element 310 comprises a clamping portion 314 with a contact area surface 316 which is configured to be supported on the support surface 128 of the mount strut 118. Furthermore, the clamping element 310 comprises a receiving portion 318 which receives the eccentric element 306. The receiving portion 318 may be pot-shaped or cylindrical.

A contact region 320 which is in contact with the eccentric element 306 is provided on the inner side of the receiving portion 318, i.e. in the direction of the axis of rotation 304. In order to prestress the contact region 320 against the eccentric element 306, the eccentric element 306 is coupled to the clamping element 310 with the aid of a spring element 322. The spring element 322 is a tension spring. The spring element 322 may be a cylindrical spring. The spring element 322 is arranged within the receiving portion 318.

Multiple joining portions 324, 326 are provided on the outer side of the clamping element 310 and used to join the clamping element 310 to a load-bearing structure or a fixed reference frame 332 via leaf spring elements 328, 330. The fixed reference frame 332 may be connected to the manipulator frame 202 or be part of the manipulator frame 202. In the present case, “fixed reference frame” means that the fixed reference frame 332 is fixed vis-à-vis the movable clamping element 310.

The clamping assembly 212C may be switched from an open state Z10 shown in FIG. 13 to a closed state Z20 shown in FIG. 14, and vice versa. The drive element 308 rotates the eccentric element 306 in order to switch the clamping assembly 212C from the open state Z10 into the closed state Z20.

By twisting the eccentric element 306, the eccentric element 306 presses the contact region 320 downward, as shown in FIG. 14, as a result of which the clamping element 310 also moves downward in the direction of the support surface 128 of the mount strut 118 together with the clamping portion 314. The spring element 322 is extended in the process, and the leaf spring elements 328, 330 are deflected.

A clamping force K is applied to the support surface 128 as soon as the contact surface 316 of the clamping element 310 makes contact with the support surface 128. The clamping force K can be metered by rotating the eccentric element 306 with the aid of the drive element 308. In order to retain particles possibly formed, the eccentric element 306, the clamping element 310 and/or the drive element 308 may be received within a particle trap, for example within a bellows.

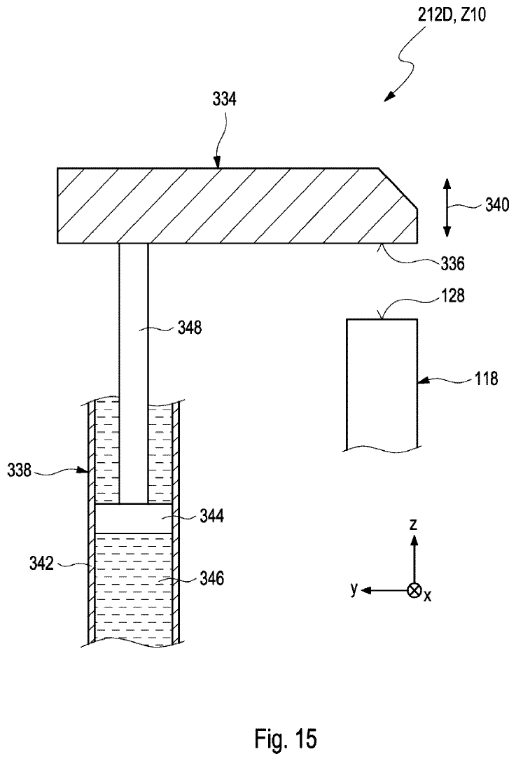

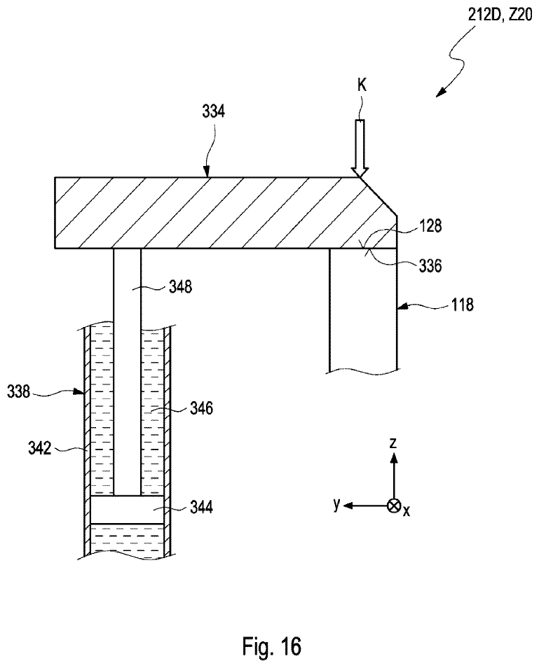

FIG. 15 shows a schematic sectional view of a further embodiment of a clamping assembly 212D. FIG. 16 shows a further schematic sectional view of the clamping assembly 212D. Hereinafter, reference is made to FIGS. 15 and 16 concurrently.

The clamping assembly 212D comprises a clamping element 334 with a contact area surface 336 which is configured to rest on the support surface 128 of the mount strut 118. With the aid of a hydraulic cylinder 338, the clamping element 334 can be moved upward and downward in the orientation of FIGS. 15 and 16, as indicated in FIG. 15 with the aid of a double-headed arrow 340.

The hydraulic cylinder 338 is a double-acting hydraulic cylinder. The hydraulic cylinder 338 comprises a housing 342 in which a piston 344 is received. The piston 344 can be acted upon on both sides by a hydraulic fluid 346. The piston 344 is coupled to the clamping element 334 with the aid of a piston rod 348.

The clamping assembly 212D may be switched from an open state Z10 shown in FIG. 15 to a closed state Z20 shown in FIG. 16, and vice versa. To switch the clamping assembly 212D from the open state Z10 to the closed state Z20, the hydraulic cylinder 338 moves the clamping element 334 downward in the orientation of FIGS. 15 and 16 until the clamping element 334 contacts the support surface 128. The clamping element 334 now applies a clamping force K to the mount strut 118.

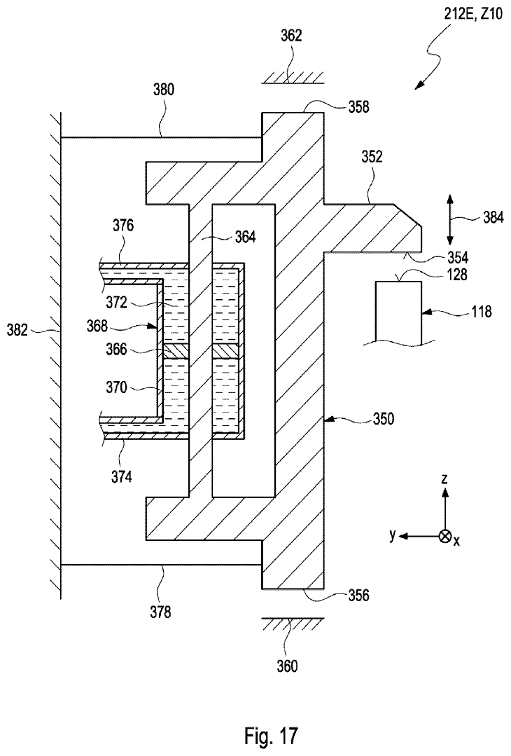

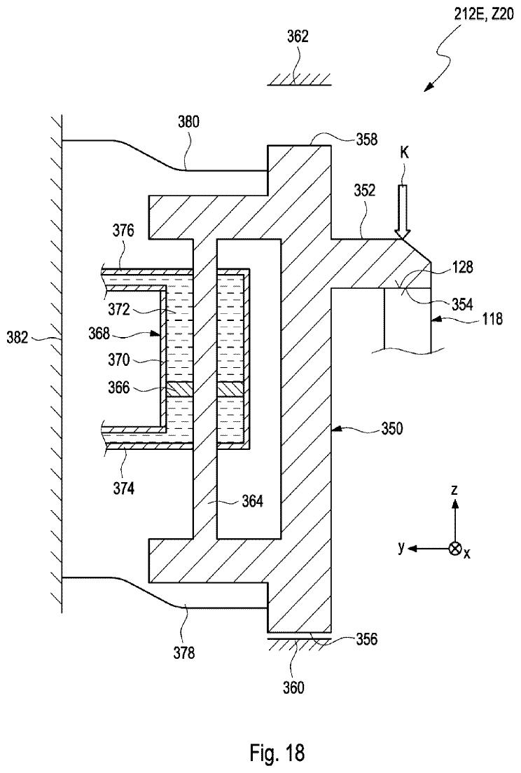

FIG. 17 shows a schematic sectional view of a further embodiment of a clamping assembly 212E. FIG. 18 shows a further schematic sectional view of the clamping assembly 212E. Hereinafter, reference is made to FIGS. 17 and 18 concurrently.

The clamping assembly 212E comprises a clamping element 350. The clamping element 350 comprises a clamping portion 352 with a contact area surface 354 which is configured to rest on the support surface 128 of the mount strut 118. The clamping element 350 furthermore comprises two stop portions 356, 358. Each stop portion 356, 358 is assigned an end stop 360, 362. The end stops 360, 362 delimit a movement of the clamping element 350 downward and upward in the orientation of FIG. 17. The stop portion 356 may come into contact with the end stop 360. The stop portion 358 may come into contact with the end stop 362.

The clamping element 350 furthermore comprises a piston rod 364. The piston rod 364 is connected to a piston 366 of a double-acting hydraulic cylinder 368. The piston 366 is received in a housing 370 of the hydraulic cylinder 368. The housing 370 is filled with a hydraulic fluid 372. The hydraulic fluid 372 may act on the housing 370 via hydraulic lines 374, 376.

The clamping element 350 is coupled to a fixed reference frame 382 with the aid of leaf spring elements 378, 380. The leaf spring elements 378, 380 are connected to the stop portions 356, 358. The fixed reference frame 382 may be coupled to the manipulator frame 202 or be part of the manipulator frame 202. With the aid of the hydraulic cylinder 368, the clamping element 350 can be moved downward and upward, as indicated in FIG. 17 with the aid of a double-headed arrow 384. The leaf spring elements 378, 380 are deformed in the process.

The clamping assembly 212E may be switched from an open state Z10 shown in FIG. 17 to a closed state Z20 shown in FIG. 18, and vice versa. To switch the clamping assembly 212E from the open state Z10 to the closed state Z20, the hydraulic cylinder 368 moves the clamping element 350 downward in the orientation of FIGS. 17 and 18 until the clamping portion 352 contacts the support surface 128. The clamping portion 352 now applies a clamping force K to the mount strut 118.

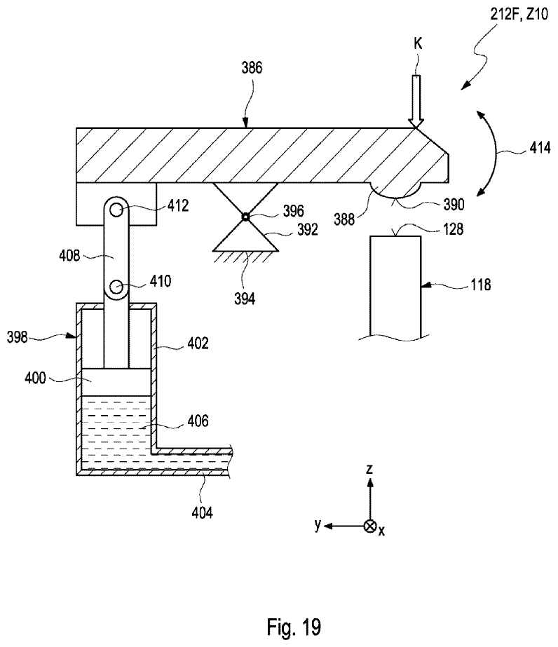

FIG. 19 shows a schematic sectional view of a further embodiment of a clamping assembly 212F.

The clamping assembly 212F comprises a clamping element 386. The clamping element 386 comprises a contact portion 388 with a spherical-cap-shaped contact surface 390. The contact surface 390 is suitable for resting on the support surface 128 of the mount strut 118. Such a contact portion 388 with an arched contact surface 390 may likewise be provided in the clamping assemblies 212B, 212C, 212D, 212E explained above.

The clamping element 386 is mounted pivotably about an axis of rotation 396 on a fixed reference frame 394 with the aid of a spring device 392. The fixed reference frame 394 may be connected to the manipulator frame 202 or be part of the manipulator frame 202. The spring device 392 may comprise multiple spring elements, for example in the form of leaf spring elements, and/or flexures.

The clamp assembly 212F further comprises a single-acting hydraulic cylinder 398 having a piston 400 received in a housing 402. A hydraulic fluid 406 is applied to the piston 400 via a hydraulic line 404. The spring device 392 prestresses the piston 400 in such a way that the hydraulic fluid 406 acts against a spring force of the spring device 392.

The piston 400 is coupled to the clamping element 386 with the aid of a coupling element 408. To this end, the coupling element 408 is connected to the piston 400 at a joining point 410 and connected to the clamping element 386 at a joining point 412.

As already described previously with respect to the different embodiments of the clamping assembly 212A, 212B, 212C, 212D, 212E, the clamping assembly 212F may be switched from an open state Z10 shown in FIG. 19 into a closed state Z20 (not shown). The hydraulic fluid 406 is applied to the piston 400 to this end. In the orientation of FIG. 19, the piston 400 is moved upward as a result. In so doing, the piston 400 works against the spring force of the spring device 392.

The clamping element 386 pivots about the axis of rotation 396, whereby the contact portion 388 is pivoted, as indicated in FIG. 19 with the aid of a double-headed arrow 414. As soon as the contact surface 390 makes contact with the support surface 128 of the mount strut 118, a clamping force K is applied thereto, as explained above.

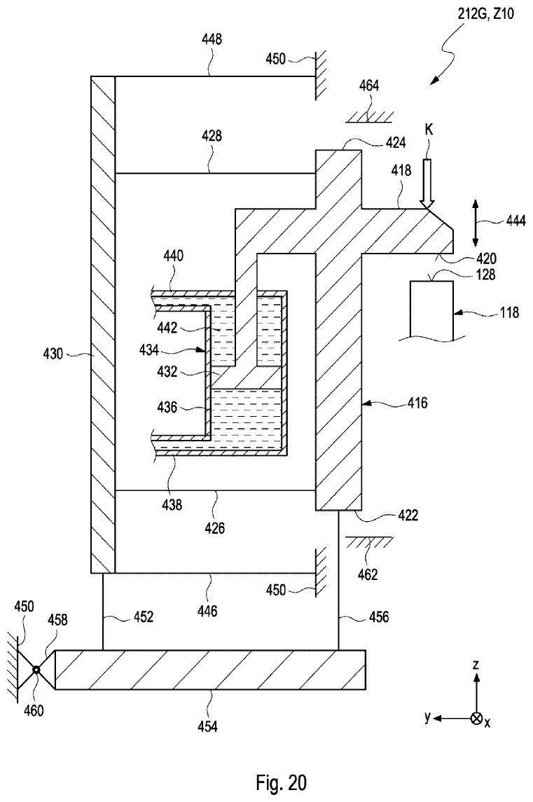

FIG. 20 shows a schematic sectional view of a further embodiment of a clamping assembly 212G.

The clamping assembly 212G comprises a clamping element 416 with a clamping portion 418. The clamping portion 418 comprises a contact area surface 420 which is configured to rest on the support surface 128 of the mount strut 118. The clamping element 416 furthermore comprises two joining portions 422, 424, with the aid of which the clamping element 416 is attached to a frame 430 via leaf spring elements 426, 428. The leaf spring elements 426, 428 may be referred to as first leaf spring elements. The frame 430 may also be referred to as first frame.

The clamping element 416 furthermore comprises a piston 432 which is part of a double-acting hydraulic cylinder 434. The hydraulic cylinder 434 comprises a housing 436 in which the piston 432 is received. A hydraulic fluid 442 may act on the piston 432 via hydraulic lines 438, 440. With the aid of the hydraulic cylinder 434, the clamping element 416 can be moved upward and downward in the orientation of FIG. 20, as indicated with the aid of a double-headed arrow 444.

The frame 430 is connected to a fixed reference frame 450 with the aid of leaf spring elements 446, 448. The fixed reference frame 450 may be connected to the manipulator frame 202 or be part of the manipulator frame 202. The leaf spring elements 446, 448 may be referred to as second leaf spring elements. Furthermore, the frame 430 is connected to a further frame 454 via a leaf spring element 452. The frame 454 may also be referred to as second frame.

The clamping element 416 is also joined to the frame 454 with the aid of a leaf spring element 456. The frame 454 is connected to the fixed reference frame 450 with the aid of a spring device 458. The spring device 458 may comprise multiple spring elements and/or flexures. The frame 454 is mounted pivotably about an axis of rotation 460 on the fixed reference frame 450 with the aid of the spring device 458.

Two end stops 462, 464 which delimit a movement of the clamping element 416 upward and downward in the orientation of FIG. 20 are assigned to the clamping element 416. In this case, the joining portion 422 is assigned the end stop 462. The end stop 464 is assigned to the joining portion 424.

As already described previously with respect to the different embodiments of the clamping assembly 212A, 212B, 212C, 212D, 212E, 212F, the clamping assembly 212G may be switched from an open state Z10 shown in FIG. 20 into a closed state Z20 (not shown). The hydraulic fluid 442 is applied to the piston 432 to this end. In the orientation of FIG. 20, the piston 432 is moved downward as a result.

A clamping force K is applied to the mount strut 118 as soon as the clamping portion 418 rests on the support surface 128 of the mount strut 118. The leaf spring elements 426, 428, 446, 448 are deflected in the process. The structural design of the clamping assembly 212G with the frames 430, 454 and the leaf spring elements 426, 428, 446, 448, 452, 456 ensures that there are no parasitic movements of the clamping element 416 in the direction of and counter to the y-direction y.

Although the present disclosure has been described on the basis of exemplary embodiments, it may be modified in a variety of ways.

### LIST OF REFERENCE SIGNS

1A Projection exposure apparatus
1B Projection exposure apparatus
2 Illumination system
3 Light source
4 Illumination optics unit
5 Object field
6 Object plane
7 Reticle
8 Reticle holder
9 Reticle displacement drive
10 Projection optics unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
24 Beam shaping and illumination system
25 Projection optics unit
26 Light source
27 Radiation
28 Photomask
29 Wafer
30 Lens element
31 Lens element
32 Lens element
33 Mirror
34 Mirror
35 Optical axis
36 Medium
100 Optical assembly
102 Central axis
104 Half axis
106 Half axis
108 Optical element
108′ Optical element
110 Optically effective surface
112 Rear side
114 Outer surface
116 Mount
118 Mount strut
120 Mount strut
122 Mount strut
124 Arm portion
126 Arm portion
128 Support surface
130 Support surface
132 Support surface
200 Optical system
202 Manipulator frame
204 Frame strut
206 Frame strut
208 Housing
210 Opening
212 Clamping assembly
212A Clamping assembly
212B Clamping assembly
212C Clamping assembly
212D Clamping assembly
212E Clamping assembly
212F Clamping assembly
212G Clamping assembly
214 Clamping assembly
216 Clamping assembly
218 Adjustment device
220 Actuator
222 Actuator
224 Actuator
226 Joining point
228 Joining point
230 Joining point
232 Load-bearing structure
234 Open-loop and closed-loop control unit
236 Axis of symmetry
238 Groove element
240 Rear side
242 Groove
244 Contact surface
246 Contact surface
248 Perforation
250 Contact element
252 Contact portion
254 Perforation
256 Rear side
258 Receiving portion
260 Decoupling element
262 Locking unit
264 Drive element
266 Locking element
268 Shaft portion
270 Head portion
270′ Head portion
272 Double-headed arrow
274 Double-headed arrow
276 Axis of symmetry
278 Base element
280 Bearing
282 Threaded spindle
284 Male thread
286 End portion
288 End portion
290 Bearing
292 Drive element
294 Bellows
296 Clamping element
298 Threaded bore
300 Contact surface
302 Double-headed arrow
304 Axis of rotation
306 Eccentric element
308 Drive element
310 Clamping element
312 Double-headed arrow
314 Clamping portion
316 Contact surface
318 Receiving portion
320 Contact region
322 Spring element
324 Joining portion
326 Joining portion
328 Leaf spring element
330 Leaf spring element
332 Fixed reference frame
334 Clamping element
336 Contact surface
338 Hydraulic cylinder
340 Double-headed arrow
342 Housing
344 Piston
346 Hydraulic fluid
348 Piston rod
350 Clamping element
352 Clamping portion
354 Contact surface
356 Stop portion
358 Stop portion
360 End stop
362 End stop
364 Piston rod
366 Piston
368 Hydraulic cylinder
370 Housing
372 Hydraulic fluid
374 Hydraulic line
376 Hydraulic line
378 Leaf spring element
380 Leaf spring element
382 Fixed reference frame
384 Double-headed arrow
386 Clamping element
388 Contact portion
390 Contact surface
392 Spring device
394 Fixed reference frame
396 Axis of rotation
398 Hydraulic cylinder
400 Piston
402 Housing
404 Hydraulic line
406 Hydraulic fluid
408 Coupling element
410 Joining point
412 Joining point
414 Double-headed arrow
416 Clamping element
418 Clamping portion
420 Contact surface
422 Joining portion
424 Joining portion
426 Leaf spring element
428 Leaf spring element
430 Frame
432 Piston
434 Hydraulic cylinder
436 Housing
438 Hydraulic line
440 Hydraulic line
442 Hydraulic fluid
444 Double-headed arrow
446 Leaf spring element
448 Leaf spring element
450 Fixed reference frame
452 Leaf spring element
454 Frame
456 Leaf spring element
458 Spring device
460 Axis of rotation
462 End stop
464 End stop
K Clamping force
M1 Mirror
M2 Mirror
M3 Mirror
M4 Mirror
M5 Mirror
M6 Mirror
R Radial direction
U Circumferential direction
x x-direction
y y-direction
z z-direction
Z1 Locked state
Z2 Unlocked state
Z10 State
Z State
Z100 State
Z200 State

What is claimed is:

1. An optical system, comprising:
an optical assembly comprising an optical element;
a manipulator frame bearing the optical assembly; and
a clamping assembly attached to the manipulator frame, the clamping assembly switchable between a closed state, in which the clamping assembly establishes a mechanical connection between the optical assembly and the manipulator frame, and an open state, in which the mechanical connection between the optical assembly and the manipulator frame is released,
wherein:
the clamping assembly comprises: a contact element connected to the optical element; a groove element connected to the manipulator frame and on which the contact element rests; and a locking unit configured to mechanically connect the contact element to the groove element in the closed state of the clamping assembly;
the contact element comprises a spherical-cap-shaped contact portion, and the groove element comprises a V-shaped groove comprising two contact surfaces oriented obliquely with respect to each other;
one of the following holds: i) the contact portion rests on the contact surfaces; or ii) the contact element and the groove element bear against each other on a surface contact or on a tetrahedron-shaped contact;
the locking unit comprises a locking element and a drive element configured to drive the locking element; and
the drive element is configured to switch the locking element between a locked state, in which the locking element engages behind the contact element to establish a form-fitting connection between the locking element and the contact element, and an unlocked state, in which the form-fitting connection between the locking element and the contact element is released.

2. The optical system of claim 1, wherein:
the contact element has a perforation;
the locking element comprises a head portion engaging behind the contact element in the locked state to establish the form-fitting connection between the locking element and the contact element; and
the head portion is guidable only through the perforation in the unlocked state.

3. The optical system of claim 1, wherein the clamping assembly comprises a clamping element and a drive element configured to displace the clamping element to switch the clamping assembly between the closed state and the open state.

4. The optical system of claim 3, further comprising a threaded spindle operatively connecting the clamping element to the drive element.

5. The optical system of claim 4, further comprising a bellows, wherein at least portions of the clamping element and/or the threaded spindle are within a bellows.

6. The optical system of claim 3, further comprising an eccentric element operatively connecting the clamping element to the drive element.

7. The optical system of claim 6, further comprising a spring element coupling the clamping element to the eccentric element, wherein the spring element prestresses the clamping element against the eccentric element.

8. The optical system of claim 3, further comprising a mount which comprises a mount strut supported on the manipulator frame, wherein, in the closed state of the clamping assembly, the clamping element applies a clamping force to the mount strut.

9. The optical system of claim 1, wherein the clamping assembly comprises a clamping element and a hydraulic cylinder configured to displace the clamping element to switch the clamping assembly between the closed state and the open state.

10. The optical system of claim 9, further comprising a fixed reference frame and elastically deformable leaf spring elements mounting the clamping element on the fixed reference frame.

11. The optical system of claim 10, wherein the clamping element is mounted on a frame via a first subset of the leaf spring elements, and wherein the frame is mounted on the fixed reference frame via a second subset of the second leaf spring elements, the second subset of the leaf spring elements being different from the first subset of the leaf spring elements.

12. The optical system of claim 9, further comprising a mount which comprises a mount strut supported on the manipulator frame, wherein, in the closed state of the clamping assembly, the clamping element applies a clamping force to the mount strut.

13. The optical system of claim 1, wherein the optical system is a microlithography projection optics unit.

14. The optical system of claim 1, wherein the optical system is a microlithography illumination optics unit.

15. The optical system of claim 1, wherein the contact portion rests on the contact surfaces.

16. The optical system of claim 1, wherein the contact element and the groove element bear against each other on a surface contact.

17. The optical system of claim 1, wherein the contact element and the groove element bear against each other on a tetrahedron-shaped contact.

18. An apparatus, comprising:
an illumination optics unit; and
a projection optics unit,
wherein:
the illumination optics unit is configured to illuminate an object field in an object plane of the projection optics unit;
the projection optics unit is configured to project the object field into an image field in an image plane of the projection optics unit;
at least one unit selected from the group consisting of the illumination optics unit and the projection optics unit comprises an optical system according to claim 1; and
the apparatus is a microlithography projection exposure apparatus.

19. An apparatus, comprising:
an illumination optics unit; and
a projection optics unit,
wherein:
the illumination optics unit is configured to illuminate an object field in an object plane of the projection optics unit;
the projection optics unit is configured to project the object field into an image field in an image plane of the projection optics unit;
the projection optics unit comprises an optical system according to claim 1; and
the apparatus is a microlithography projection exposure apparatus.

20. An apparatus, comprising:
an illumination optics unit; and
a projection optics unit,
wherein:
the illumination optics unit is configured to illuminate an object field in an object plane of the projection optics unit;
the projection optics unit is configured to project the object field into an image field in an image plane of the projection optics unit;
illumination optics unit comprises an optical system according to claim 1; and
the apparatus is a microlithography projection exposure apparatus.
